(19) United States
(12) Patent Application Publication
(10) Pub. No.: US 2011/0157998 A1
(43) Pub. Date: Jun. 30, 2011

(54) SEMICONDUCTOR MEMORY DEVICE AND METHOD OF OPERATING THE SAME

(75) Inventor: Chang Won YANG, Icheon-si (KR)

(73) Assignee: HYNIX SEMICONDUCTOR INC., Icheon-si (KR)

(21) Appl. No.: 12/982,434

(22) Filed: Dec. 30, 2010

(30) Foreign Application Priority Data
Dec. 31, 2009 (KR) 10-2009-0135633

(51) Int. Cl. G11C 16/06; G11C 16/04

(52) U.S. Cl. 365/185.22; 365/185.24

(57) ABSTRACT

A method of operating a semiconductor memory device comprises performing a third program such that threshold voltages of third memory cells, from among memory cells of a selected page, are higher than a third level, after the third program loop is completed, performing a second program loop such that threshold voltages of second memory cells, from among the memory cells, are lower than the third level, but higher than a second level, and after the second program loop is completed, performing a first program loop such that threshold voltages of first memory cells, from among the memory cells, are lower than the second level, but higher than a first level.

### CROSS-REFERENCE TO RELATED APPLICATION

Priority to Korean patent application number 10-2009-0135633 filed on Dec. 31, 2009, the entire disclosure of which is incorporated by reference herein, is claimed.

### BACKGROUND

Exemplary embodiments relate to a semiconductor memory device and a method of operating the same and, more particularly, to a NAND flash memory device and a method of operating the same.

In a common semiconductor memory device, data of 1 bit is stored in a memory cell. In a NAND flash memory device, however, data of 2 bits or more may be stored in a memory cell. Accordingly, the memory capacity can be improved.

The threshold voltage of a memory cell is changed according to data stored in the memory cell. For example, in case where data of 1 bit is stored in the memory cell, if the threshold voltage of the memory cell is lower than 0 V, data stored in the memory cell is read as ‘1’. If the threshold voltage of the memory cell is higher than 0 V, data stored in the memory cell is read as ‘0’.

Meanwhile, in case where data of 2 bits are stored in the memory cell, the threshold voltage of the memory cell is changed according to data stored in the memory cell. For example, if the threshold voltage of the memory cell is lower than 0 V, data stored in the memory cell is read as ‘11’. If the threshold voltage of the memory cell is in a first level Vpv1 (e.g., 0.2 V to 0.8 V), data stored in the memory cell is read as ‘01’. If the threshold voltage of the memory cell is in a second level Vpv2 (e.g., 1.4 V to 1.1 V), data stored in the memory cell is read as ‘10’. If the threshold voltage of the memory cell is in a third level Vpv3 (2.8 V to 3.4 V), data stored in the memory cell is read as ‘00’.

In order to raise the threshold voltage of a memory cell, a high program voltage has to be supplied to a corresponding word line and the control gate of the memory cell. However, with a rise in the degree of integration, a gap between the memory cells is narrowed, and so all neighboring memory cells are influenced by the program voltage. Consequently, an interference phenomenon in which the threshold voltages of the memory cells abnormally rise is generated. If the interference phenomenon increases, it is difficult to distinguish data stored in the memory cells, which may lead to a read failure.

### BRIEF SUMMARY

Exemplary embodiments relate to a semiconductor memory device and a method of operating the same, which are capable of minimizing an interference phenomenon occurring when a program operation is performed.

A method of operating a semiconductor memory device according to an exemplary embodiment of the present invention includes performing a third program such that the threshold voltages of third memory cells, from among the memory cells of a selected page, are higher than a third level, after the third program loop is completed, performing a second program loop such that the threshold voltages of second memory cells, from among the memory cells, are lower than the third level, but higher than a second level, and after the second program loop is completed, performing a first program loop such that the threshold voltages of first memory cells, from among the memory cells, are lower than the second level, but higher than a first level.

A method of operating a semiconductor memory device according to another exemplary embodiment of the present invention includes performing a third program such that the threshold voltages of third memory cells, from among the memory cells of a selected page, are higher than a third level, after the third program loop is completed, performing a first program loop such that the threshold voltages of first and second memory cells, from among the memory cells, are lower than the third level, but higher than a first level, and after the first program loop is started, performing a second program loop such that the threshold voltages of the second memory cells are lower than the third level, but higher than a second level.

A semiconductor memory device according to yet another exemplary embodiment of the present invention includes a memory array configured to include a plurality of memory cells, an operation circuit group configured to perform program loops for changing the threshold voltages of the memory cells to different levels according to date stored in the memory cells, and a control circuit configured to control the operation circuit group such that a program loop for memory cells having threshold voltages rising to a highest level, from among the program loops, is performed first, and then remaining program loops for memory cells having threshold voltages rising to the remaining levels are performed.

### BRIEF DESCRIPTION OF THE DRAWINGS

FIG. 1 is a block diagram of a semiconductor memory device according to an exemplary embodiment of the present invention.

FIGS. 2A and 2B are graphs illustrating a method of operating the semiconductor memory device according to an exemplary embodiment of the present invention.

FIGS. 3A and 3D are graphs illustrating a method of operating the semiconductor memory device according to another exemplary embodiment of the present invention.

FIG. 4 is a graph illustrating a method of supplying program voltages and verification voltages in a method of operating the semiconductor memory device according to yet another exemplary embodiment of the present invention.

FIG. 5 is a graph illustrating a method of supplying program voltages and verification voltages in a method of operating the semiconductor memory device according to further yet another exemplary embodiment of the present invention.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

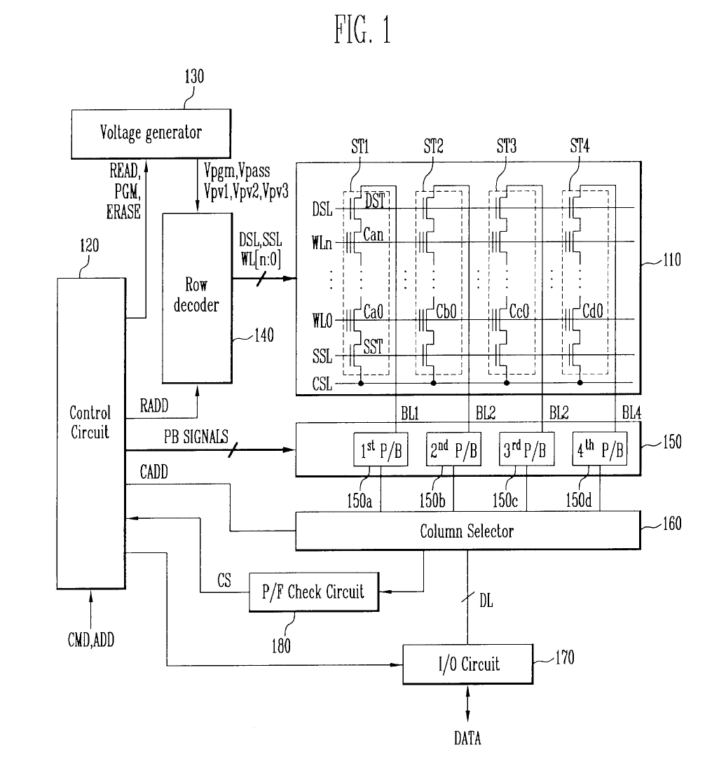

FIG. 1 is a block diagram of a semiconductor memory device according to an exemplary embodiment of the present invention.

Referring to FIG. 1, the semiconductor memory device according to the exemplary embodiment of the present invention includes a memory array 110, an operation circuit group (consisting of elements 130, 140, 150, 160, and 170), a pass/fail (P/F) check circuit 180, and a control circuit 120.

The memory array 110 includes a plurality of memory blocks. Only one memory block is shown in FIG. 1, for convenience' sake. Each of the memory blocks includes a plurality of strings ST0 to ST4 coupled between bit lines BL1 to BL4 and a common source line CSL. That is, the strings ST1 to ST4 are coupled to the respective bit lines BL1 to BL4 and in common coupled to the common source line CSL. Each (e.g., ST1) of the strings includes a source select transistor SST having a source coupled to the common source line CSL, a plurality of memory cells Ca0 to Cdn, and a drain select transistor DST having a drain coupled to the bit line BL1. The gates of the source select transistors SST of the strings ST1 to ST4 are coupled to a source select line SSL, the gates of the memory cells Ca0 to Cdn are coupled to respective word lines WL0 to WLn, and the gates of the drain select transistors DST of the strings ST1 to ST4 are coupled to a drain select line DSL.

In a NAND flash memory device, memory cells included in a memory block may be classified into a physical page unit and a logical page unit. The page (or an even page and an odd page) may be the basic unit of a program operation or a read operation.

For example, the memory cells Ca0 to Cd0 coupled to a word line (for example, WL0) may constitute a physical page. Even-numbered memory cells Ca0 and Cc0 coupled to a word line (for example, WL0) may constitute an even physical page, and odd-numbered memory cells Cb0 and Cd0 coupled to the word line WL0 may constitute an odd physical page. In a NAND flash memory device, according to a known art, an erase operation is performed per a memory block, and a read operation or a program operation is performed per a page.

The control circuit 120 generates internal command signals PGM, READ, and ERASE for a program operation, a read operation, and an erase operation in response to a command signal CMD and also generates control signals PB SIGNALS for controlling page buffers 150a to 150d of a page buffer group 150 according to the types of the operations. The control circuit 120 generates a row address signal RADD and a column address signal CADD in response to an address signal ADD. The control circuit 120 checks whether the threshold voltages of selected memory cells have risen to at least a target voltage in response to a check signal CS generated by the P/F check circuit 180, and controls a subsequent operation (for example, the program operation of a next page) according to a result of the check. A detailed operation of the control circuit 120 is described later.

In the case of a NAND flash memory device, the operation circuit group may include the voltage generators 130 and 140, the page buffer group 150, the column selector 160, and the I/O circuit 170.

The voltage supply unit (130 and 140) generates operating voltages for the read operation, the program operation, and the erase operation of memory cells in response to the internal command signals READ, PGM, and ERASE of the control circuit 120, and supplies the operating voltages to the local lines DSL, WL0 to WLn, and DSL of a selected memory block in response to the row address signal RADD. The voltage supply unit includes the voltage generator 130 and the row decoder 140.

The voltage generator 130 generates the operating voltages for programming, reading, and erasing memory cells to global lines in response to the internal command signals READ, PGM, and ERASE of the control circuit 120. In particular, in case where the program operation is performed, the voltage generator 130 generates a program voltage Vpgm, a pass voltage Vpass, and verification voltages Vpv1, Vpv2, and Vpv3 to the global lines in response to the internal command signal for programming PGM.

The row decoder 140 transfers the operating voltages Vpgm, Vpass, Vpv1, Vpv2, and Vpv3 to the local lines DSL, WL0 to WLn, and SSL of a memory block selected from among the memory blocks of the memory array 110 in response to the row address signals RADD of the control circuit 120. That is, the operating voltages are supplied to the lines DSL, WL[n:0], and SSL of a selected memory block.

The page buffer group 150 includes the page buffers 150a to 150d coupled to the respective bit lines BL1 to BL4. The page buffer group 150 supplies voltages, necessary to store data in the memory cells Ca0, Cb0, Cc0, and Cd0, to the respective bit lines BL1 to BL4 in response to the control signals PB SIGNALS of the control circuit 120. More particularly, the page buffers 150a to 150d precharge the bit lines BL1 to BL4 when the program operation, the erase operation, or the read operation of the memory cells Ca0, Cb0, Cc0, and Cd0 is performed, or the page buffers 150a to 150d latch data corresponding to the threshold voltages of the memory cells Ca0, Cb0, Cc0, and Cd0 detected according to a change in the voltages of the bit lines BL1 to BL4. That is, the page buffer group 150 controls the voltages of the bit lines BL1 to BL4 according to data stored in the memory cells Ca0, Cb0, Cc0, and Cd0 and detects data stored in the memory cells Ca0, Cb0, Cc0, and Cd0.

The column selector 160 selects the page buffers 150a to 150d of the page buffer group 150 in response to the column address signal CADD of the control circuit 120. Data to be stored in memory cells is inputted to a page buffer selected by the column selector 160, or data detected from memory cells is outputted from the selected page buffer.

The I/O circuit 170 transfers external data to the column selector 160 under the control of the control circuit 120 such that the external data is inputted to the page buffers 150a to 150d. If the data from the column selector 160 is sequentially inputted to the page buffers 150a to 150d, the page buffers 150a to 150d store the received data in their internal latches. The I/O circuit 170 externally outputs data received from the page buffers 150a to 150d via the column selector 160.

The P/F check circuit 180 checks whether all the threshold voltages of selected memory cells have risen to at least a target voltage in a program verification operation performed after a program operation in which the program voltage Vpgm is supplied to a selected word line in order to store data in the selected memory cells (that is, in order to raise the threshold voltages of the selected memory cells by means of the program operation). The P/F check circuit 180 outputs the check signal CS to the control circuit 120 according to a result of the check.

The control circuit 120 controls a level of the program voltage Vpgm supplied to a selected word line in the program operation of memory cells, and controls the voltage generator 130 such that the verification voltages Vpv1, Vpv2, and Vpv3 can be selectively supplied to a selected word line in a program verification operation. Here, the control circuit 120 may control the voltage generator 130 in response to the check signal CS of the P/F check circuit 180.

Hereinafter, a method of operating the semiconductor memory device described above is described in detail. For example, it is assumed that the memory cell Ca0 is a program-inhibited cell for storing data ‘11’ (that is, cell remained in an erase state), the first memory cell Cb0 has a threshold voltage rising up to a voltage level between a first level Vpv1 and a second level Vpv2, in order to store data ‘01’. Also, it is assumed that the second memory cell Cc0 has a threshold voltage rising up to a voltage level between the second level Vpv2 and a third level Vpv3, in order to store data ‘10’, and the third memory cell Cd0 has a threshold voltage rising up to at least the third level Vpv3 in order to store data ‘00’. The correspondence between the stored data and the ranges of the threshold voltages may be changed.

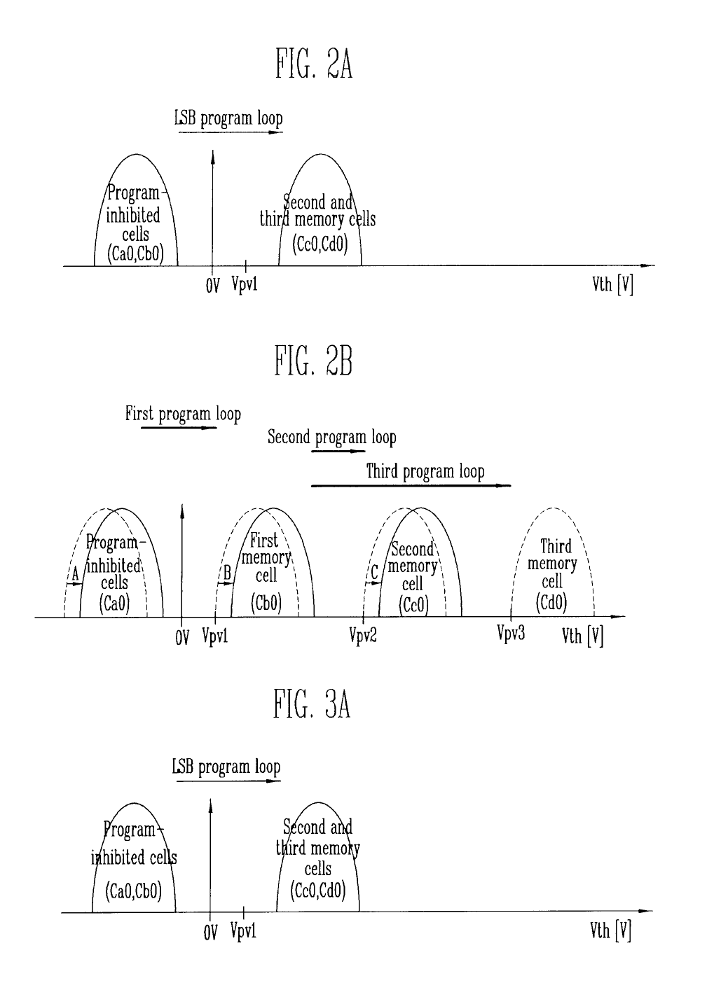

FIGS. 2A and 2B are graphs illustrating a method of operating the semiconductor memory device according to an exemplary embodiment of the present invention.

Referring to FIGS. 1 and 2A, data are stored in memory cells of an erase state. Accordingly, all the threshold voltages of memory cells in which data will be stored are set to a level lower than 0 V. That is, all the memory cells are set to a state of data ‘11’.

Next, a program loop for raising the threshold voltages of the second and third memory cells Cc0 and Cd0 whose threshold voltages have to rise higher than the second level Vpv2 and the third level Vpv3, respectively, higher than the first level Vpv1 is performed. In other words, the program loop is performed to raise the threshold voltages of the memory cells Cc0 and Cd0 in which ‘0’ must be stored as a least significant bit when data of 2 bits is stored in a memory cell. The program loop is referred to as a Least Significant Bit (LSB) program loop (or LSB program operation).

If the LSB program loop is performed, an amount that the threshold voltages of the second and third memory cells Cc0 and Cd0 have to further rise in a subsequent operation (for example, Most Significant Bit (MSB) program loop (or MSB program operation)) decreases. Next, in order to store MSB data from among data of 2 bits, an MSB program loop is performed such that the threshold voltages of the first to third memory cells Cb0, Cc0, and Cd0 are higher than the first to third levels Vpv1, Vpv2, and Vpv3, respectively. The MSB program loop includes first to third program loops. This is described in detail below.

Referring to FIGS. 1 and 2B, the first program loop is performed such that the threshold voltage of the first memory cell Cb0, from among the memory cells Ca0, Cb0, Cc0, and Cd0 of a selected page, is higher than the first level Vpv1 (0<Vpv1). The first program loop includes a first program operation of supplying a first program voltage to the word line WL0 and a first program verification operation for detecting the threshold voltage of the first memory cell Cb0 by using a verification voltage of the first level Vpv1 (hereinafter referred to as a first verification voltage). The first program loop is repeatedly performed while raising the first program voltage until the threshold voltage of the first memory cell Cb0 becomes higher than the first level Vpv1. In the first program loop, the threshold voltages of the second and third memory cells Cc0 and Cd0 may rise.

Even though the first program voltage is supplied to all the memory cells Ca0, Cb0, Cc0, and Cd0, if different voltages are supplied to the bit lines coupled to the memory cells Ca0, Cb0, Cc0, and Cd0, only the threshold voltages of the selected memory cells Cb0, Cc0, and Cd0 can rise. For example, if a program-inhibited voltage (for example, Vcc) is supplied to the bit line BL1 coupled to the memory cell Ca0, and a program permission voltage (for example, a ground voltage) is supplied to the bit lines BL2, BL3, and BL4 of the first to third memory cells Cb0, Cc0, and Cd0 whose threshold voltages will be raised, only the threshold voltages of the memory cells Cb0, Cc0, and Cd0 rise. This operation may be applied to all subsequent program operations likewise.

Before or after the first program loop is completed, the second program loop may be performed such that the threshold voltage of the second memory cell Cc0 becomes higher than the second level Vpv2 (Vpv1<Vpv2). The second program loop includes a second program operation of supplying a second program voltage to the word line WL0 and a second program verification operation for detecting the threshold voltage of the second memory cell Cc0 by supplying the second verification voltage Vpv2 to the word line WL0. Here, the first program verification operation of the first program loop may continue to be performed in the second program loop. The second program loop is repeatedly performed while raising the second program voltage until the threshold voltage of the second memory cell Cc0 becomes higher than the second level Vpv2.

Before or after the second program loop is completed, the third program loop may be performed such that the threshold voltage of the third memory cell Cd0 is higher than the third level Vpv3 (Vpv2<Vpv3). Accordingly, the threshold voltages of the memory cells Ca0, Cb0, Cc0, and Cd0 may be set to different levels according to data stored in the memory cells.

According to this example, since the second and the third program loops are performed after the first program loop is completed, an interference may occur in the first memory cell Cb0 during the second program loop for raising the threshold voltages of the second and third memory cells Cc0 and Cd0. Consequently, the threshold voltages of the first memory cell Cb0, of which the first program loop is completed, may rise. During the third program loop for raising the threshold voltage of the third memory cell Cd0, an interference may occur in the first and second memory cells Cb0 and Cc0, thereby raising the threshold voltages of the first and second memory cells Cb0 and Cc0. Likewise, the threshold voltage of the program-inhibited cell Ca0 also may rise.

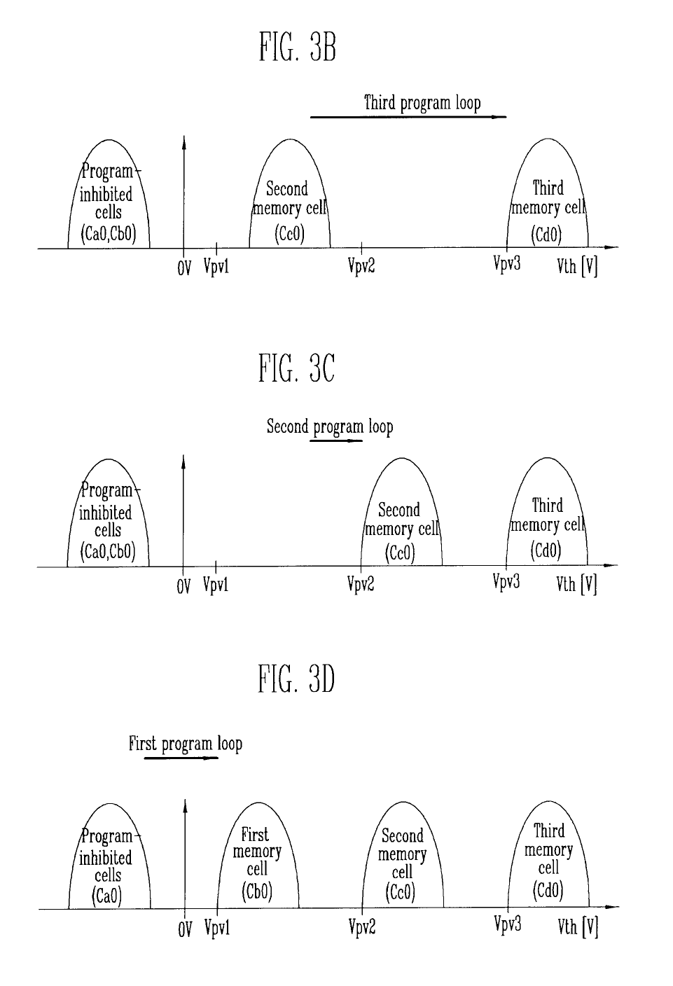

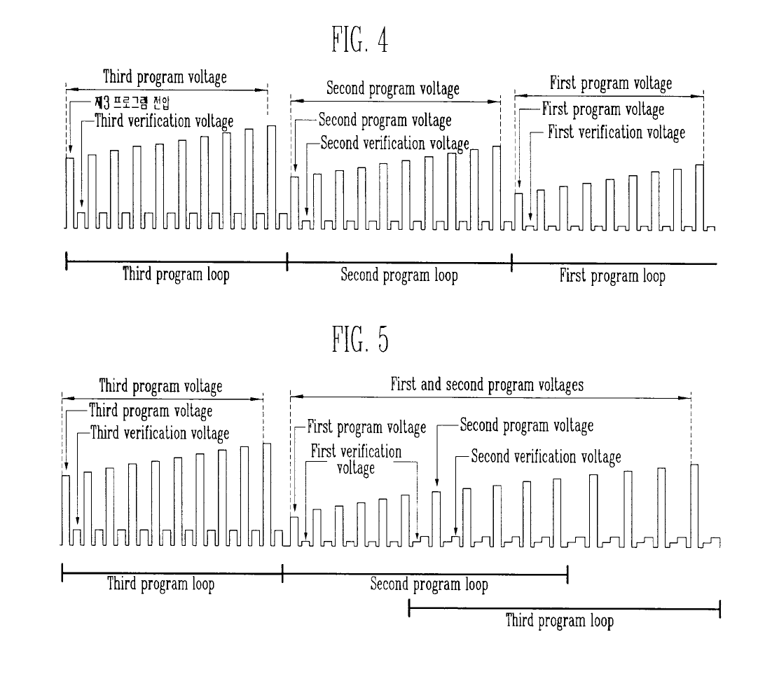

FIGS. 3A and 3D are graphs illustrating a method of operating the semiconductor memory device according to another exemplary embodiment of the present invention. FIG. 4 is a graph illustrating a method of supplying program voltages and verification voltages in a method of operating the semiconductor memory device according to yet another exemplary embodiment of the present invention.

Referring to FIG. 3A, an LSB program loop is performed in order to raise the threshold voltages of the second and third memory cells Cc0 and Cd0 whose threshold voltages have to rise higher than the second level Vpv2 and the third level Vpv3, respectively. The LSB program loop may be performed using the same method as described with reference to FIG. 2A, and a description thereof is omitted.

Referring to FIGS. 3B and 4, a third program loop is performed such that the threshold voltage of the third memory cell Cd0 is higher than the third level Vpv3. The third program loop includes a third program operation of supplying a third program voltage to the word line WL0 in order to raise the threshold voltage of the third memory cell Cd0, and a third program verification operation of supplying the third verification voltage Vpv3 to the word line WL0. The third program operation and the third program verification operation are repeatedly performed while raising the third program voltage until the threshold voltage of the third memory cell Cd0 becomes higher than the third level Vpv3. The third program voltage may be raised from a level, lower than the highest value of the second program voltage, up to a level higher than the highest value of the second program voltage in the second program operation of the second program loop.

Referring to FIGS. 3C and 4, after the third program loop is completed, a second program loop is performed such that the threshold voltage of the second memory cell Cc0 is higher than the second level Vpv2. The second program loop includes a second program operation of supplying a second program voltage to the word line WL0 in order to raise the threshold voltage of the second memory cell Cc0, and a second program verification operation of supplying the second verification voltage Vpv2 to the word line WL0. The second program operation and the second program verification operation are repeatedly performed while raising the second program voltage until the threshold voltage of the second memory cell Cc0 becomes higher than the second level Vpv2. The second program voltage may be raised from a level, lower than the highest value of the first program voltage, up to a level higher than the highest value of the first program voltage in the first program operation of the first program loop.

Referring to FIGS. 3D and 4, after the second program loop is completed, a first program loop is performed such that the threshold voltage of the first memory cell Cb0 is higher than the first level Vpv1. The first program loop includes a first program operation of supplying a first program voltage to the first memory cell Cb0, and a first program verification operation of supplying the first verification voltage Vpv1 to the word line WL0. The first program operation and the first program verification operation are repeatedly performed while raising the first program voltage until the threshold voltage of the first memory cell Cb0 becomes higher than the first level Vpv1. The first program voltage may be raised from a level lower than the lowest second program voltage in the second program operation of the second program loop.

If the threshold voltages of the first to third memory cells Cb0, Cc0, and Cd0 are raised according to the above method, an interference may occur in the second and third memory cells Cc0 and Cd0. However, since relatively low program voltages are supplied in the second program loop and the first program loop, the amount that the threshold voltages of the second and third memory cells Cc0 and Cd0 are raised may decrease.

FIG. 5 is a graph illustrating a method of supplying program voltages and verification voltages in a method of operating the semiconductor memory device according to further yet another exemplary embodiment of the present invention.

Referring to FIG. 5, an LSB program loop (refer to FIG. 3A) is performed and a third program loop (refer to FIG. 3B) is then performed. Next, a first program loop (refer to FIG. 3D) is performed and a second program loop (refer to FIG. 3C) is then performed.

The first program loop may be performed before the second program loop is completed. During the time for which the first and second program loops are performed or the second program loop is performed, a first program verification operation using the first verification voltage Vpv1 and a second program verification operation using the second verification voltage Vpv2 may be consecutively performed.

Meanwhile, since the first and second program loops are partially overlapped and consecutively performed, the first and second program voltages of the memory cells have continuity. That is, the second program voltage is voltage raised from the first program voltage. In other words, a program voltage supplied in the first and second program loops continues to rise. A program voltage supplied in a program operation between program verification operations when only the first program verification operation is performed becomes the first program voltage. A program voltage supplied in a program operation between the first and second verification operations and other first and second verification operations when the first and second verification operations are consecutively performed becomes the second program voltage.

If the threshold voltages of the first to third memory cells Cb0, Cc0, and Cd0 are raised according to the above method, an interference may occur. However, since a program voltage having a lower level than a program voltage supplied in the third program loop is supplied in the first and second program loops, the amount that the threshold voltages of the first and third memory cells Cb0 and Cd0 rise may decrease.

According to the embodiments of this disclosure, since an interference phenomenon between memory cells is minimized in a program operation, a probability of an occurrence of failure due to the interference phenomenon may decrease.

Furthermore, since a widening of a distribution of threshold voltages decreases, reliability of the operation may be improved.

What is claimed is:

1. A method of operating a semiconductor memory device, comprising:
performing a third program such that threshold voltages of third memory cells of a selected page are higher than a third level;
after the third program loop is completed, performing a second program loop such that threshold voltages of second memory cells of the selected page are lower than the third level, but higher than a second level; and
after the second program loop is completed, performing a first program loop such that threshold voltages of first memory cells of the selected page are lower than the second level, but higher than a first level.

2. The method of claim 1, wherein:
the third program loop comprises a third program operation of supplying a third program voltage to the third memory cells and a third program verification operation using a third verification voltage,
the second program loop comprises a second program operation of supplying a second program voltage to the second memory cells and a second program verification operation using a second verification voltage, and
the first program loop comprises a first program operation of supplying a first program voltage to the first memory cells and a first program verification operation using a first verification voltage.

3. The method of claim 2, wherein:
the third program operation and the third program verification operation are repeatedly performed while raising the third program voltage until the threshold voltages of the third memory cells become higher than the third level, and
the third program voltage rises from a level lower than the highest value of the second program voltage, up to a level higher than the highest value of the second program voltage.

4. The method of claim 2, wherein:
the second program operation and the second program verification operation are repeatedly performed while raising the second program voltage until the threshold voltages of the second memory cells become higher than the second level, and
the second program voltage rises from a level lower than the highest value of the first program voltage, up to a level higher than the highest value of the first program voltage.

5. The method of claim 2, wherein the first program operation and the first program verification operation are repeatedly performed while raising the first program voltage until the threshold voltages of the first memory cells become higher than the first level.

6. The method of claim 1, further comprising performing a program loop for raising the threshold voltages of the second and third memory cells up to a level higher than the first level, before performing the third program loop.

7. A method of operating a semiconductor memory device, comprising:
performing a third program such that threshold voltages of third memory cells of a selected page are higher than a third level;
after the third program loop is completed, performing a first program loop such that threshold voltages of first and second memory cells of the selected page are lower than the third level, but higher than a first level; and
after the first program loop is started, performing a second program loop such that the threshold voltages of the second memory cells are lower than the third level, but higher than a second level.

8. The method of claim 7, wherein:
the first program loop is performed before the second program loop is completed, and
program verification operations of the first and second memory cells are consecutively performed while the first and second program loops are performed.

9. The method of claim 8, wherein:
the third program loop comprises a second program operation of supplying a third program voltage to the third memory cells and a third program verification operation using a third verification voltage,
the first program loop comprises a first program operation of supplying a first program voltage to the first and second memory cells and a first program verification operation using a first verification voltage, and
the second program loop comprises a second program operation of supplying a second program voltage to the second memory cells, the first program verification operation using the first verification voltage, and a second program verification operation using a second verification voltage.

10. The method of claim 9, wherein:
the third program operation and the third program verification operation are repeatedly performed while raising the third program voltage until the threshold voltages of the third memory cells become higher than the third level, and
the third program voltage rises from a level lower than the highest value of the second program voltage, up to a level higher than the highest value of the second program voltage.

11. The method of claim 9, wherein the first program operation and the first program verification operation are repeatedly performed while raising the first program voltage until the threshold voltages of the first memory cells become higher than the first level.

12. The method of claim 9, wherein in the second program loop, the second program operation, the first program verification operation, and the second program verification operation are repeatedly performed while raising the second program voltage until the threshold voltages of the second memory cells become higher than the second level, wherein the second program voltage is voltage raised from the first program voltage.

13. The method of claim 7, further comprising performing a program loop for raising the threshold voltages of the second and third memory cells up to a level higher than the first level, before performing the third program loop.

14. A semiconductor memory device, comprising:
a memory array configured to include a plurality of memory cells;
an operation circuit group configured to perform program loops for changing threshold voltages of the memory cells to different levels according to date stored in the memory cells; and
a control circuit configured to control the operation circuit group such that a program loop for rising threshold voltages of memory cells to a highest level, from among the program loops, is performed first, and then remaining program loops for rising threshold voltages of memory cells to remaining levels are performed.

15. The semiconductor memory device of claim 14, wherein the control circuit controls the operation circuit group such that a second program loop for rising the threshold voltages of second memory cells to a second level lower than the highest level and a first program loop for rising the threshold voltages of first memory cells to a first level lower than the second level are performed, after a third program loop for rising threshold voltages of third memory cells to the highest level is performed.

16. The semiconductor memory device of claim 15, wherein the control circuit controls the operation circuit group such that the first program loop is performed earlier than the second program loop.

17. The semiconductor memory device of claim 15, wherein the operation circuit group is configured to:
repeatedly perform the third program loop while raising a program voltage until the threshold voltages of the third memory cells become higher than the third level;
repeatedly perform the second program loop while raising a program voltage until the threshold voltages of the second memory cells become higher than the second level; and
repeatedly perform the first program loop while raising a program voltage until the threshold voltages of the first memory cells become higher than the first level.

18. The semiconductor memory device of claim 14, wherein the control circuit controls the operation circuit group such that a first program loop for rising the threshold voltages of first memory cells to a first level lower than the highest level is performed, after a second program loop for rising threshold voltages of second memory cells to the highest level is performed.

19. The semiconductor memory device of claim 18, wherein the operation circuit group is configured to:
repeatedly perform the second program loop while raising a program voltage until the threshold voltages of the second memory cells become higher than the highest level; and
repeatedly perform the first program loop while raising a program voltage until the threshold voltages of the first memory cells become higher than the first level.
